(19) United States
(12) Patent Application Publication
(10) Pub. No.: US 2025/0226835 A1
(43) Pub. Date: Jul. 10, 2025

(54) METHOD AND APPARATUS TO OBTAIN AN EXTRA BIT OF RESOLUTION IN A SINGLE-ENDED SAR ADC

(71) Applicant: Reconceive AI, Inc., San Carlos, CA (US)

(72) Inventors: Jorge A. Grilo, Berkeley, CA (US); Ronald E. Gagnon, Jr., Berkeley, CA (US); Charles Prince Buchbinder, San Carlos, CA (US)

(21) Appl. No.: 19/011,579

(22) Filed: Jan. 6, 2025

Related U.S. Application Data
(60) Provisional application No. 63/618,231, filed on Jan. 5, 2024.

(51) Int. Cl. H03M 1/46

(52) U.S. Cl. CPC H03M 1/462; H03M 1/466

(57) ABSTRACT

A single-ended successive approximation register (SAR) digital-to-analog converter (ADC) includes, in part, an array of N capacitors each having a first plate coupled to a first node. A second plate of each of the N capacitors is coupled to an associated one of N different switches configured to connect the second plate of the capacitor to a ground voltage or a reference voltage. The SAR ADC also includes a comparator having a first input receiving the voltage of the first node, and a second input that receives the reference voltage if the voltage at the first node during a first phase is smaller than the reference voltage. The second input to the comparator receives twice the reference voltage if the voltage at the first node during the first phase is greater than the reference voltage.

### RELATED APPLICATION

The present application claims benefit under 35 USC 119(e) of U.S. Patent Application Ser. No. 63/618,231, filed Jan. 5, 2024, the content of which is incorporated herein by reference in its entirety.

### BACKGROUND

Successive-approximation (SAR) Analog-to-Digital converters (ADCs) often employ top-plate sampling to resolve the Most Significant Bit (MSB) at no additional cost of hardware. In an ADC, the MSB indicates whether the input signal is in the upper or lower half of the full range, or sign in a signed representation.

### BRIEF DESCRIPTION OF THE DRAWINGS

The following Detailed Description, Figures, and appended Claims signify the nature and advantages of the innovations, embodiments and/or examples of the claimed inventions. All of the Figures signify innovations, embodiments, and/or examples of the claimed inventions for purposes of illustration only and do not limit the scope of the claimed inventions. Such Figures are not necessarily drawn to scale, and are part of the Disclosure.

FIG. 1 is a schematic diagram of a single-ended DAC array, in accordance with one embodiment of the present disclosure.

FIG. 2 is an example of the timing operation of the DAC array of FIG. 1, in accordance with one embodiment of the present disclosure.

FIG. 3A illustrates exemplary waveforms of the successive approximation when the input voltage is less than half the reference voltage Vref for various bits of the DAC array, in accordance with one embodiment of the present disclosure.

FIG. 3B illustrates exemplary waveforms of the successive approximation when the input voltage is greater than half the reference voltage Vref for various bits of the DAC array, in accordance with one embodiment of the present disclosure.

### DETAILED DESCRIPTION

Analog-to-digital signal conversion may be accomplished with differential topologies. The way the MSB of an ADC is resolved may rely on the determination of the sign of the sampled input signal which is presented directly to a comparator's inputs; if it is positive the MSB is “1”, otherwise the MSB is “0”. The remainder of the array is utilized to resolve the N−1 bits if the total number of ADC bits is N. The technique is beneficial in that it uses less area compared to a full binary array and consumes less power as there is no dedicated digital-to-analog converter (DAC) element (a capacitor, or current source, or other).

However, the above technique may not be readily applicable to a single-ended implementation where bottom-plate sampling is used. In bottom-plate sampling, the input signal is sampled at the bottom of the capacitors. In a subsequent phase, the capacitors are connected to ground so as to charge the shared top plate to −C_{DAC}Vᵢₙ, where C_{DAC} is the total array capacitance, and Vᵢₙ is the input voltage. The algorithm proceeds to connect each capacitor in succession to the reference voltage searching for the configuration that results in a top plate voltage Vx that is closest to ground (the reference for comparison in the example). The MSB is resolved through the dedicated capacitor. The top plate has negative charge initially, and connecting capacitors to the positive reference voltage raises the top plate voltage by a positive fraction of the reference. With a binary array, the totality of capacitors can add V_{ref} to the top plate.

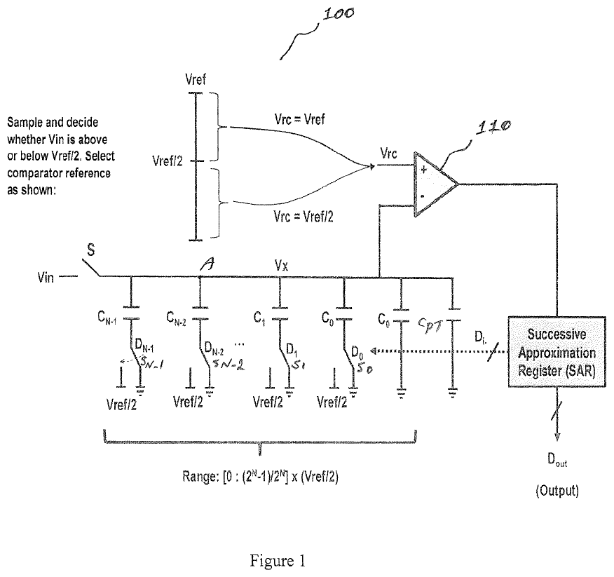

In accordance with one aspect of the present disclosure, a single-ended SAR achieves (N+1) bits of resolution using an N-bit DAC array and top capacitor plate sampling. FIG. 1 is a schematic diagram of a single-ended DAC array 100, in accordance with one exemplary embodiment of the present disclosure. DAC array 100 is shown as including, in part, a single-end comparator 110, and an array 200 of N capacitors C₀, C₁ . . . C_{N-1}, that achieves N bits of resolution.

As shown in FIG. 1, positive input signal Vᵢₙ is shown as being sampled on the top plates of the capacitors when switch S is closed. The voltage Vx on the top plates of the capacitors (i.e., node A) is adapted to increase by coupling the capacitors to the reference Vref/2. Comparator 110 is adapted to compare the voltage at node A to a predefined positive reference Vrc applied to the positive terminal of the comparator.

Single-ended DAC array 100 operates as follows. Assume, without loss of generality, that the input signal range is between zero and a reference voltage Vref. As such, the most significant bit (MSB) of the DAC array will determine whether the signal is above or below Vref/2, the mid-point in the signal range.

When the signal Vᵢₙ is sampled onto the top plate at node A, the comparator compares the signal with Vref/2. (The comparator can track the input while it's sampling to save time.) Depending on the result of the comparison, voltage Vrc remains either at Vref/2 (Input Vin<Vref/2) or is set to Vref (Input Vin>Vref/2) in the ensuing bit-cycle decisions.

The capacitive array can add to the top plate up to approximately Vref/2 through charge redistribution. If the signal is below Vref/2, this ensures that the top plate voltage can be resolved around Vref/2 (the comparator reference). If the signal is above Vref/2, this ensures that the top plate voltage can be resolved around Vref (the comparator reference).

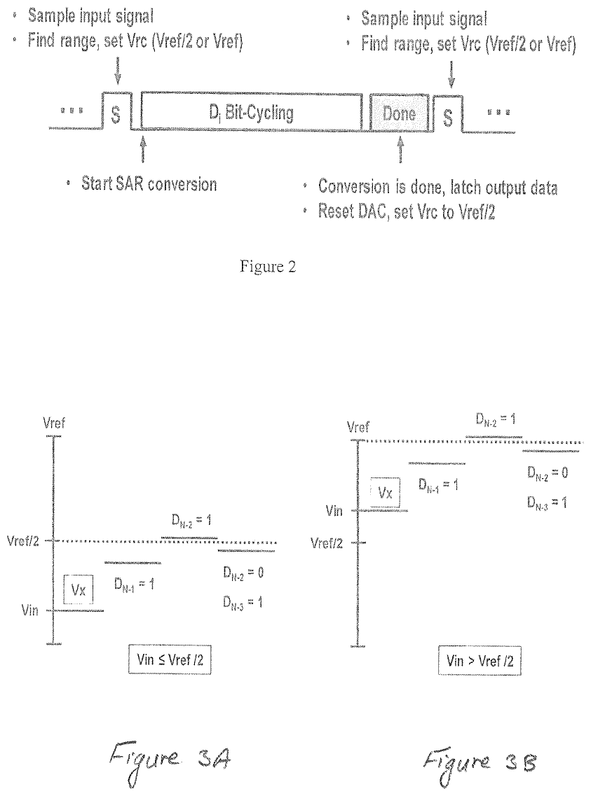

FIG. 2 is an example of the timing operation of the DAC array 100, in accordance with one embodiment of the present disclosure. In a first phase, switch S closes, sampling the input signal relative to ground on all the DAC array capacitors C₀:CN−1 and parasitic capacitor C_{pT}. During this first phase, the comparator tracks the input signal and at the end of the phase decides whether Vᵢₙ is above or below Vref/2. Based on that decision, Vrc is set as described above. The SAR algorithm commences, connecting each capacitor in succession (starting with C_{N-1}) to Vref/2 via an associated switch (such as switch S_{N-1} associated with capacitor C_{N-1}) and deciding whether the top plate voltage Vx exceeds Vrc. If it does not, the tested capacitor remains connected to Vref/2; if Vx exceeds Vrc, the tested capacitor is connected again to ground. The following capacitor is connected to Vref/2 (FIGS. 3A and 3B) and the process repeats. Once all bits have been exercised (“Done” in FIG. 2), the SAR algorithm concludes, and the DAC control bits are latched to form the output signal. If, for example, the cap associated with, for example, C_{N-1} is connected to ground, it means D_{N-1} is zero, and if it is connected to Vref/2, it means D_{N-1} is one. During this phase, the DAC array capacitances are discharged to ground, and Vrc is set to Vref/2 in preparation for the next conversion cycle (when switch S closes).

FIG. 3A illustrates exemplary waveforms of the successive approximation when Vin is less than Vref/2 for various bits of the DAC array. FIG. 3B illustrates exemplary waveforms of the successive approximation when Vin is greater than Vref/2 for various bits of the DAC array. The SAR operation, in accordance with embodiments of the present disclosure may be synchronous or asynchronous. It is understood that the above embodiment of the present disclosure is only an example. For example, embodiments of the present disclosure equally apply if, for example, the input and reference signs reverse, or if the voltages are based on a common-mode reference.

Embodiments of the present disclosure provide a number of advantages. Among these advantages are the dynamic assignment of a comparator reference that resolves the MSB without a dedicated array capacitor. After the value of Vrc has been decided, it can be assigned during the first bit cycle if the DAC reference settles within a defined period. Vrc does not change for the remaining bit cycles.

To avoid a dead zone or discontinuity around Vref/2, the DAC reference (“Vref/2”) is calibrated to compensate for the gain loss due to parasitic capacitance on the top plate (C_{pT} in FIG. 1). Undercompensating results in a dead zone (insufficient range); whereas overcompensating results in a discontinuity (excessive range); in addition to the nonlinearity, both lead to gain errors. The precision of the calibration depends on the overall requirements for the ADC.

Alternatively, non-radix-2 (<2) solutions may be employed but would require additional hardware and steps to derive the correct conversion code. Such techniques utilize redundancy to recover from wrong decisions. Since the capacitor array only resolves half of the input signal range, it consumes less energy.

The figures illustrate embodiments of the present disclosure as they apply to a binary array. It is understood, however, that embodiments of the present disclosure may be equally applied to arrays with different weighting or a combination of capacitor weights and reference voltages, if the combined range can generate Vref/2 (half of the input range).

The above exemplary embodiments of the present disclosure depicted a switched-capacitor DAC array, but it is understood that embodiments of the present disclosure equally apply, for example, current sources, resistive dividers, and the like.

What is claimed is:

1. A single-ended successive approximation register (SAR) digital-to-analog converter (ADC):
an array of N capacitors each having a first plate coupled to a first node, wherein a second plate of each of the N capacitors is coupled to an associated one of N different switches configured to connect the second plate of the capacitor to a ground voltage or a reference voltage;
a comparator having a first input receiving the voltage of the first node, and a second input that receives the reference voltage if the voltage at the first node during a first phase is smaller than the reference voltage, wherein the second input to the comparator receives twice the reference voltage if the voltage at the first node during the first phase is greater than the reference voltage.
